(19) United States
(12) Patent Application Publication
(10) Pub. No.: US 2025/0380477 A1
(43) Pub. Date: Dec. 11, 2025

(54) BIPOLAR TRANSISTOR HAVING COLLECTOR WITH A RETROGRADE DOPING PROFILE

(71) Applicant: SKYWORKS SOLUTIONS, INC., Irvine, CA (US)

(72) Inventors: Kai Hay Kwok, Burlington, MA (US); Cristian Cismaru, Newbury Park, CA (US)

(21) Appl. No.: 19/228,878

(22) Filed: Jun. 5, 2025

Related U.S. Application Data
(60) Provisional application No. 63/656,770, filed on Jun. 6, 2024.

(51) Int. Cl. H10D 62/13; H03F 3/21; H03F 3/213; H10D 10/01; H10D 10/80

(52) U.S. Cl. CPC H10D 62/137; H10D 10/021; H10D 10/821; H03F 3/211; H03F 3/213; H03F 2200/222; H03F 2200/318

(57) ABSTRACT

This disclosure relates to bipolar transistors, such as heterojunction bipolar transistors, having retrograde doping concentration in the collector. One aspect of this disclosure is a bipolar transistor that includes a collector having a retrograde doping profile in which a doping concentration is highest at a junction of the base and the collector and decreases through a portion of the collector to about 95% less to about 99.5% less. Such bipolar transistors can be implemented, for example, in power amplifiers.

### CROSS REFERENCE TO RELATED APPLICATIONS

This application claims priority under 35 U.S.C. § 119 (e) to U.S. Provisional Application Ser. No. 63/656,770 titled “BIPOLAR TRANSISTOR HAVING COLLECTOR WITH A RETROGRADE DOPING PROFILE” filed on Jun. 6, 2024, the disclosure of which is herein incorporated by reference in its entirety.

### BACKGROUND

### Field of Disclosure

The present disclosure relates to the field of semiconductor structures and, more particularly, to bipolar transistors and products that include bipolar transistors.

### Description of Related Technology

Bipolar transistors, such as heterojunction bipolar transistors (HBTs), are implemented in a wide variety of electronics applications. Such bipolar transistors can be formed on semiconductor substrates, such as gallium arsenide (GaAs) substrates. One illustrative application for a bipolar transistor is in a power amplifier system. In some cases, specifications for power amplifier systems, such as for the error vector magnitude (EVM), can be demanding to meet. Accordingly, a need exists for improved linearity in systems that include bipolar transistors, such as power amplifier systems.

The Error Vector Magnitude (EVM) performance of a power amplifier (PA) is an important parameter if the power amplifier is intended for a linear mode of operation in applications such as WiFi. In order to achieve good EVM, constellation points in a modulated waveform must be amplified as accurately as possible by the power amplifier so that there is no amplitude or phase distortion in the waveform at the output of the power amplifier. Since the amplitude of a signal in a complex modulation scheme varies greatly with time, the phase shift and the gain of the power amplifier must be very stable over a wide range of power levels to keep the EVM as low as possible.

While the static EVM of the power amplifier is improved, the power amplifier needs to be rugged or be able to operate without breaking down especially under impedance mismatch conditions at the output. Therefore, the safe operating area (SOA) or ruggedness of transistors in the power amplifier need to be maintained while the EVM of the power amplifier is improved by reducing the RF gain expansion or compression as the output power increases.

### SUMMARY OF THE INVENTION

The innovations described in the claims each have several aspects, no single one of which is solely responsible for its desirable attributes. Without limiting the scope of this invention, some prominent features will now be briefly discussed.

In accordance with an aspect, there is provided a bipolar transistor formed on a substrate. The bipolar transistor may include a collector, a base disposed over the collector, and an emitter. The collector may have a retrograde doping profile in which a doping concentration is highest at a junction of the base and the collector and decreases through a portion of the collector to about 95% less to about 99.5% less, e.g., about 95% less, about 96% less, about 97% less, about 98% less, about 99% less, or about 99.5% less.

In some embodiments, the decrease in doping concentration in the collector may be through about one-twentieth to about one-quarter of a total dimension of the collector.

In some embodiments, the bipolar transistor may have an output power of at least about 28 dBm within a frequency band centered around about 6.5 GHz.

In some embodiments, the doping concentration in the collector decreases substantially linearly or substantially non-linearly.

In some embodiments, the bipolar transistor may have about a 0.3 dB improvement in gain expansion as compared to a similarly constructed bipolar transistor with a collector having a uniformly doped or step-doped concentration. In some embodiments, the bipolar transistor may have approximately the same ruggedness as a function of a voltage at a collector-emitter junction as compared to a similarly constructed bipolar transistor with a collector having a uniform doping concentration. In further embodiments, the bipolar transistor may have about a 35% increase in the transition frequency flatness as compared to a similarly constructed bipolar transistor with a collector having a uniformly doped or step-doped concentration.

The doping concentration of the collector at the junction of the base and the collector may be selected from a range of 3×10¹⁶ cm⁻³ to 6×10¹⁷ cm⁻³, e.g., about 3×10¹⁶ cm⁻³, about 4×10¹⁶ cm⁻³, about 5×10¹⁶ cm⁻³, about 6×10¹⁶ cm⁻³, about 7×10¹⁶ cm⁻³, about 8×10¹⁶ cm⁻³, about 9×10¹⁶ cm⁻³, about 1×10¹⁷ cm⁻³, about 2×10¹⁷ cm⁻³, about 3×10¹⁷ cm⁻³, about 4×10¹⁷ cm⁻³, about 5×10¹⁷ cm⁻³, or about 6×10¹⁷ cm⁻³. For example, in the collector disclosed herein, the collector may have a total thickness of 1 μm to 2 μm and the doping concentration in the collector may be at a maximum within a first 0.2 μm to 0.4 μm of the base-collector junction.

In further embodiments, the bipolar transistor may include a sub-collector with the collector being disposed between the base and the sub-collector. For bipolar transistors including a sub-collector, the doping concentration of the collector at the junction of the collector and the sub-collector may be selected from a range of 5×10¹⁶ cm⁻³ to 5×10¹⁷ cm⁻³, e.g., about 5×10¹⁶ cm⁻³, about 6×10¹⁶ cm⁻³, about 7×10¹⁶ cm⁻³, about 8×10¹⁶ cm⁻³, about 9×10¹⁶ cm⁻³, about 1×10¹⁷ cm⁻³, about 2×10¹⁷ cm⁻³, about 3×10¹⁷ cm⁻³, about 4×10¹⁷ cm⁻³, or about 5×10¹⁷ cm⁻³.

In some embodiments, the bipolar transistor may be a heterojunction bipolar transistor (HBT). In some embodiments, the bipolar transistor may be a GaAs transistor.

In accordance with an aspect, there is provided a power amplifier module comprising a bipolar transistor formed on a substrate. The bipolar transistor may include a collector, a base disposed over the collector, and an emitter. The collector may have a retrograde doping profile in which a doping concentration is highest at a junction of the base and the collector and decreases through a portion of the collector to about 95% less to about 99.5% less, e.g., about 95% less, about 96% less, about 97% less, about 98% less, about 99% less, or about 99.5% less.

In some embodiments, the bipolar transistor of the power amplifier module may have an error vector magnitude that is no greater than about −47 dBc at an output power of about 16 dBm when the power amplifier operates within a frequency band centered around about 6.5 GHz.

In some embodiments, the retrograde doping profile of the collector of the bipolar transistor may be configured to provide about a 0.3 dB improvement in gain expansion as compared to a similarly constructed bipolar transistor with a collector having a uniformly doped or step-doped concentration. In some embodiments, the retrograde doping profile of the collector of the bipolar transistor may be configured to provide approximately the same ruggedness as a function of a voltage at a collector-emitter junction as compared to a similarly constructed bipolar transistor with a collector having a uniform doping concentration. In some embodiments, the retrograde doping profile of the collector of the bipolar transistor may be configured to provide about a 35% increase in the transition frequency flatness as compared to a similarly constructed bipolar transistor with a collector having a uniformly doped or step-doped concentration.

In some embodiments, wherein the collector may have a doping concentration of at the junction of the base and the collector of at least 3×10¹⁶ cm⁻³ in a first about 0.2 μm to 0.4 μm of thickness of the collector.

In accordance with an aspect, there is provided a mobile or fixed wireless device. The mobile or fixed wireless device may include an antenna, a battery, and a power amplifier including a bipolar transistor formed on a substrate. The bipolar transistor of the power amplifier may include a collector, a base disposed over the collector, and an emitter. The collector of the bipolar transistor may have a retrograde doping profile in which a doping concentration is highest at a junction of the base and the collector and decreases through a portion of the collector to about 95% less to about 99.5% less, e.g., about 95% less, about 96% less, about 97% less, about 98% less, about 99% less, or about 99.5% less. The retrograde doping profile may be configured to provide about a 0.3 dB improvement in gain expansion as compared to a similarly constructed bipolar transistor with a collector having a uniform or graded doping concentration.

In accordance with an aspect, there is provided a method of forming a bipolar transistor on a substrate. The method may include forming a sub-collector on the substrate. The method may include forming a collector on the sub-collector. The formed collector may have a retrograde doping profile in which a doping concentration is highest at a junction of a base and the collector and decreases through a portion of the collector to about 95% less to about 99.5% less, e.g., about 95% less, about 96% less, about 97% less, about 98% less, about 99% less, or about 99.5% less. The method further may include forming a base on the collector. The method additionally may include forming an emitter on the base.

In some embodiments, the doping concentration of the collector at the junction of the base and the collector may be selected from a range of 3×10¹⁶ cm⁻³ to 6×10¹⁷ cm⁻³, e.g., about 3×10¹⁶ cm⁻³, about 4×10¹⁶ cm⁻³, about 5×10¹⁶ cm⁻³, about 6×10¹⁶ cm⁻³, about 7×10¹⁶ cm⁻³, about 8×10¹⁶ cm⁻³, about 9×10¹⁶ cm⁻³, about 1×10¹⁷ cm⁻³, about 2×10¹⁷ cm⁻³, about 3×10¹⁷ cm⁻³, about 4×10¹⁷ cm⁻³, about 5×10¹⁷ cm⁻³, or about 6×10¹⁷ cm⁻³.

In some embodiments, the doping concentration of the collector at the junction of the collector and the sub-collector may be selected from a range of 5×10¹⁶ cm⁻³ to 5×10¹⁷ cm⁻³, e.g., about 5×10¹⁶ cm⁻³, about 6×10¹⁶ cm⁻³, about 7×10¹⁶ cm⁻³, about 8×10¹⁶ cm⁻³, about 9×10¹⁶ cm⁻³, about 1×10¹⁷ cm⁻³, about 2×10¹⁷ cm⁻³, about 3×10¹⁷ cm⁻³, about 4×10¹⁷ cm⁻³, or about 5×10¹⁷ cm⁻³.

### BRIEF DESCRIPTION OF THE DRAWINGS

The accompanying drawings are not drawn to scale. In the drawings, each identical or nearly identical component that is illustrated in the various figures may be represented by a like numeral. For purposes of clarity, not every component may be labeled in every drawing. In the drawings:

FIG. 1 illustrates a cross-section of a bipolar transistor according to an embodiment.

FIG. 2 is a graph of experimental data illustrating no significant change in ruggedness for a bipolar transistor of this disclosure and a state-of-the-art bipolar transistor.

FIG. 3 is a graph of experimental data illustrating a flatter normalized transition frequency (f_{T}) for a bipolar transistor of this disclosure and a state-of-the-art bipolar transistor.

FIG. 4 is a graph of experimental data illustrating reduced distortion or gain expansion in amplitude from input to output for a bipolar transistor of this disclosure and a state-of-the-art bipolar transistor.

FIG. 5 is a graph of experimental data illustrating the increase in gain at high current or high power output for a bipolar transistor of this disclosure and a state-of-the-art bipolar transistor.

FIG. 6 illustrates a flow diagram of a method of forming a bipolar transistor according to an embodiment.

FIG. 7 illustrates a block diagram of a power amplifier module that includes a bipolar transistor with one or more features described herein.

FIG. 8 illustrates block diagram of a mobile device that includes the power amplifier module illustrated in FIG. 7.

### DETAILED DESCRIPTION

Data transmission rates are expected to continue increasing with every component and system update. Thus, a reduction of distortion in power amplifier (PA) modules can be desirable. Modulation schemes with high data rates (for example, 5G or 5th Generation Wireless) generally require higher output power than previous generations. Similarly, to help with thermal management and preserve the system battery life, it can be beneficial to increase amplifier efficiency. To achieve lower cost and smaller form factor, design solutions often obtain the best performance when they push the physical limits of the GaAs-based HBTs in regards to electrical stress.

Amplifier linearity measurements can include channel power ratios, such as an adjacent channel power ratio (ACPR1) and an alternative channel power ratio (ACPR2), and/or channel leakage power ratios, such as an adjacent channel leakage power ratio (ACLR1) and an alternative channel leakage power ratio (ACLR2). ACPR2 and ACLR2 can be referred to as second channel linearity measurements. ACPR2 and ACLR2 values can correspond to measurements at an offset of about 1.98 MHz from a frequency of interest. Measurement of linearity can also include EVM (Error Vector Magnitude), a measure of modulation accuracy, represented by the variation in amplitude from input to output (AM-AM distortion) and variation in phase from input to output as a result of amplitude variation (AM-PM). EVM can also have dynamic elements (DEVM) and static elements (SEVM) as some elements of distortion can vary as a function of time. Even systems that use DPD (Digital Pre-Distortion) to help linearize the output can have several limitations such that the intrinsic linearity of the GaAs-based HBT amplifiers can benefit from meeting specific criteria.

In some situations, the most linear amplifier mode is Class-A, but some compact mobile handset GaAs HBT amplifiers target classes and architectures that can obtain higher efficiency. In practice, some modern amplifiers operate in Class-AB or in switching modes such as Class-E when the output can be linearized with DPD or other schemes. Additional benefits in efficiency can be found with systems that raise or lower the output power supply V_{cc} using a separate or integrated PMIC (Power Management Integrated Circuit) such as a system that uses APT (Average Power Tracking) or ET (Envelope Tracking). As an example, when a handset battery's output is raised or lowered, e.g., from 3.4 V, by a PMIC with V_{cc} provided by a buck-boost converter, efficiency can be improved. Some ET systems can use V_{cc}=5V or 5.5 V when peak RF output power is desired such that the Class-E amplifier has output collectors that see 3×Vcc at peak power. When compared to a system with V_{cc} fixed to 3.4 V, it is apparent that such systems could greatly benefit from GaAs-based HBT devices that are more rugged, or that have a wider or larger Safe Operating Area (SOA).

Aspects of the present disclosure relate to a bipolar transistor having a retrograde doping concentration, i.e., highest at an interface and decreasing over distance, for example, at least about 3×10¹⁶ cm⁻³ to about 6×10¹⁷ cm⁻³, in a first collector region abutting a base and at least one grading in another collector region adjacent the first collector region. A high doping concentration in a first collector region abutting a base of the bipolar transistor can improve one or more linearity measures in power amplifier systems. However, a high doping concentration in the first collector region can also decrease the gain of the bipolar transistor, such as the RF gain. To offset the decrease in the gain resulting from the high doping concentration in the first collector region, a retrograde doping profile can be included in the front portion of the collector to transition from the initially high doping concentration at the base-collector junction towards a sub-collector. In some embodiments, the one or more other collector regions include two different gradings in which the doping concentration is held constant, or the doping concentration varies (for example, increases) at a different rate away from the base. Properly selecting the grading(s) and the retrograde doping concentration in the first collector region can result in desirable RF gain and linearity characteristics of the bipolar transistor, especially compared to a bipolar transistor including a flat doped or step doped collector structure.

Experimental data indicates that power amplifier systems that include such bipolar transistors can meet demanding linearity specifications and also meet RF gain specifications. For instance, a power amplifier system including such a bipolar transistor has an output power of at least about 28 dBm within a frequency band centered around about 6.5 GHz.

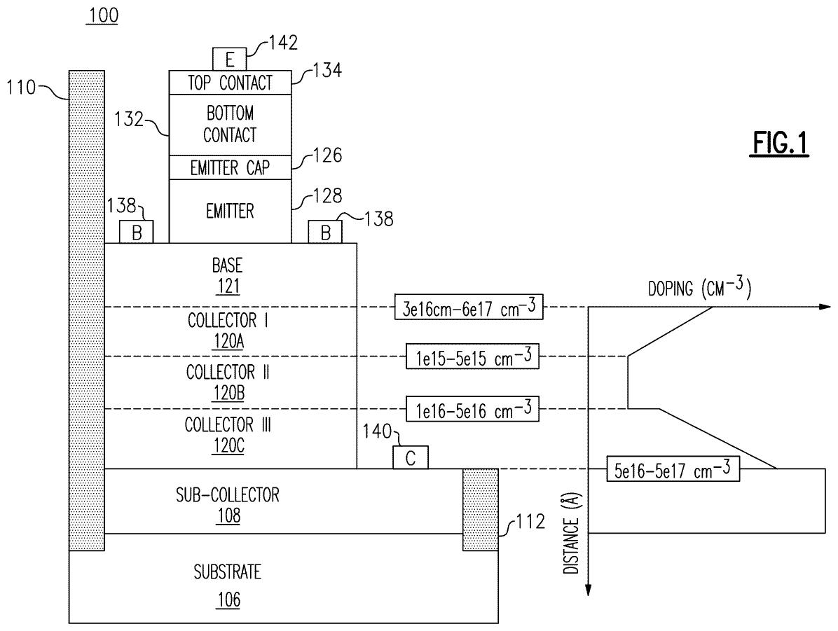

FIG. 1 shows an illustrative cross section of a bipolar transistor 100 according to an embodiment. As illustrated, the bipolar transistor 100 is a heterojunction bipolar transistor (HBT). The bipolar transistor 100 can be formed on a substrate 106. The substrate 106 can be a semiconductor substrate, such as a GaAs substrate. The bipolar transistor 100 can be disposed between isolation regions 110 and 112. Isolation regions 110 and 112 are non-conductive regions that can provide electrical isolation between the bipolar transistor 100 and an adjacent transistor or other circuit element. Isolations regions 110 and 112 can each include, for example, a trench filled with nitride, polyimide, or other material suitable for electrical isolation. Although not shown, it will be understood that one or more buffer layers can be included between the substrate 106 and the sub-collector 108. The one or more buffer layers can include implant damaged material that renders such material semi-insulating.

The bipolar transistor 100 can include a collector, a base 121, and an emitter 128. The collector can include a plurality of collection regions having different doping profiles. For instance, the collector can include a first collector region 120A abutting the base 121, a second collector region 120B under the first collector region 120A, and a third collector region 120C under the second collector region 120B.

The first collector region 120A can abut the base 121 to form a collector-base junction. The collector-base junction can be a p-n junction. The first collector region 120A can include N⁺ doped GaAs. The first collector region 120A can be a sloped doped region with an initially elevated dopant concentration that decreases as the thickness of the first collector region 120A increases. The doping concentration in the first collector region 120A at the collector-base interface of the bipolar transistor 100 can influence linearity of a system that includes the bipolar transistor 100.

For instance, the doping concentration of the first collector region 120A together with the thickness of the first collector region 120A can influence the EVM of a power amplifier system. Lower doping concentrations of the first collector region 120A together with smaller thickness of the first collector region 120A may not achieve a desired level of EVM. In contrast, higher doping concentrations of the first collector region 120A together with larger thickness of the first collector region 120A may degrade a gain of the bipolar transistor 100 such that a system including the bipolar transistor 100 does not meet gain specifications, such as RF gain specifications. In view of this trade-off, particular values of the doping concentration of the first collector region 120A and the thickness of the first collector region 120A may need to be selected to achieve both a desired gain and a desired linearity. As one example, the collector can have a retrograde doping profile in which a doping concentration is highest at a junction of the base and the collector and decreases through a portion of the collector, i.e., the first collector region 120A, to about 95% less to about 99.5% less. The retrograde doping profile in the collector decreases either substantially linearly (as illustrated in FIG. 1) or substantially non-linearly.

The first collector region 120A of the collector can have a doping concentration that is selected to meet EVM specifications of a power amplifier system that includes the bipolar transistor 100. As one example, the first collector region 120A can have a doping concentration selected such that a system that includes the bipolar transistor 100 has an output power of at least about 28 dBm within a frequency band centered around about 6.5 GHz. In some embodiments, the first collector region 120A can have a doping concentration selected such that a system that includes the bipolar transistor 100 has about a 0.3 dB improvement in gain expansion as compared to a similarly constructed bipolar transistor with a collector having a uniformly doped or step-doped concentration. In some embodiments, the first collector region 120A can have a doping concentration selected such that a system that includes the bipolar transistor 100 has approximately the same ruggedness as a function of a voltage at a collector-emitter junction as compared to a similarly constructed bipolar transistor with a collector having a uniform doping concentration. In other embodiments, the first collector region 120A can have a doping concentration selected such that a system that includes the bipolar transistor 100 has about a 35% increase in the transition frequency flatness as compared to a similarly constructed bipolar transistor with a collector having a uniformly doped or step-doped concentration.

The retrograde doping profile dimension in to the overall collector dimension, i.e., the first collector region 120A, is through about one-twentieth to about one-quarter of a total dimension of the collector, e.g., about 1/20, about 1/19, about 1/18, about 1/17, about 1/16, about 1/15, about 1/14, about 1/13, about 1/12, about 1/11, about 1/10, about 1/9, about ⅛, about 1/7, about ⅙, about ⅕, or about ¼ of a total dimension of the collector. For a collector that has an overall thickness of about 2 μm, the retrograde doping profile, i.e., the first collector region 120A, can be about 1000 Å to about 5000 Å, e.g., about 1000 Å, about 1100 Å, about 1200 Å, about 1300 Å, about 1400 Å, about 1500 Å, about 1600 Å, about 1700 Å, about 1800 Å, about 1900 Å, about 2000 Å, about 2100 Å, about 2200 Å, about 2300 Å, about 2400 Å, about 2500 Å, about 2600 Å, about 2700 Å, about 2800 Å, about 2900 Å, about 3000 Å, about 3100 Å, about 3200 Å, about 3300 Å, about 3400 Å, about 3500 Å, about 3600 Å, about 3700 Å, about 3800 Å, about 3900 Å, about 4000 Å, about 4100 Å, about 4200 Å, about 4300 Å, about 4400 Å, about 4500 Å, about 4600 Å, about 4700 Å, about 4800 Å, about 4900 Å, or about 5000 Å.

For a collector that has an overall thickness of about 1 μm, the retrograde doping profile, i.e., the first collector region 120A, can be about 500 Å to about 2500 Å, e.g., about 500 Å, about 600 Å, about 700 Å, about 800 Å, about 900 Å, about 1000 Å, about 1100 Å, about 1200 Å, about 1300 Å, about 1400 Å, about 1500 Å, about 1600 Å, about 1700 Å, about 1800 Å, about 1900 Å, about 2000 Å, about 2100 Å, about 2200 Å, about 2300 Å, about 2400 Å, or about 2500 Å.

As illustrated in FIG. 1, the doping concentration of the collector at the junction of the base and the collector is selected from a range of 3×10¹⁶ cm⁻³ to 6×10¹⁷ cm⁻³, e.g., about 3×10¹⁶ cm⁻³, about 4×10¹⁶ cm⁻³, about 5×10¹⁶ cm⁻³, about 6×10¹⁶ cm⁻³, about 7×10¹⁶ cm⁻³, about 8×10¹⁶ cm⁻³, about 9×10¹⁶ cm⁻³, about 1×10¹⁷ cm⁻³, about 2×10¹⁷ cm⁻³, about 3×10¹⁷ cm⁻³, about 4×10¹⁷ cm⁻³, about 5×10¹⁷ cm⁻³, or about 6×10¹⁷ cm⁻³. For example, in the collector disclosed herein, the collector may have a total thickness of 1 μm to 2 μm and the doping concentration in the collector may be at a maximum within a first 0.2 μm to 0.4 μm of the base-collector junction. Any thickness or dimension range or value can be implemented in combination with any of the doping concentrations disclosed herein.

A uniformly high doping concentrations in the first collector region 120A of the collector can reduce the RF gain of the bipolar transistor 100. In order to meet RF gain specifications of a system that includes the bipolar transistor 100, such as a power amplifier system, a retrograde doping profile can counteract such a decrease in RF gain. As illustrated in FIG. 1, the collector includes one or more gradings in other collector regions 120B, 120C of the bipolar transistor 100. These other collector regions, having different gradings than the first collector region 120A, can also compensate for some of the losses in RF gain associated with a higher doping concentration in the first collector region 120A.

The other collector regions 120B, 120C can include multiple gradings in which doping varies at different rates. As illustrated in FIG. 1, the other collector regions 120B, 120C can include a second collector region 120B that has a substantially constant doping concentration about 95% less to about 99.5% less than the first collector region 120A and a third collector region 120C having a positively graded doping profile to achieve a balance between PA ruggedness and RF gain. In other implementations, the first collector region 120A and the third collector region 120C can have respective doping concentrations that change in the appropriate direction at substantially the same rate. Any of the doping concentrations of any of the first collector region 120A, second collector region 120B, and third collection region 120C can vary linearly or non-linearly (for example, parabolically). In the example illustrated in FIG. 1, the doping concentrations of the first collector region 120A and third collection region 120C can both have doping concentrations that vary linearly.

As illustrated in FIG. 1, the doping concentration between the first collector region 120A and the second collector region 120B is about 95% less to about 99.5% less than the doping concentration of the collector at the junction of the base and the collector. This doping concentration is selected from a range of 1×10¹⁵ cm⁻³ to 3×10¹⁶ cm⁻³, e.g., about 1×10¹⁵ cm⁻³, about 1.5×10¹⁵ cm⁻³, about 2×10¹⁵ cm⁻³, about 2.5×10¹⁵ cm⁻³, about 3×10¹⁵ cm⁻³, about 3.5×10¹⁵ cm⁻³, about 4×10¹⁵ cm⁻³, about 4.5×10¹⁵ cm⁻³, about 5×10¹⁵ cm⁻³, about 5.5×10¹⁵ cm⁻³, about 6×10¹⁵ cm⁻³, about 6.5×10¹⁵ cm⁻³, about 7×10¹⁵ cm⁻³, about 7.5×10¹⁵ cm⁻³ about 8×10¹⁵ cm⁻³, about 8.5×10¹⁵ cm⁻³, about 9×10¹⁵ cm⁻³, about 9.5×10¹⁵ cm⁻³, about 1×10¹⁶ cm⁻³, about 1.5×10¹⁶ cm⁻³, about 2×10¹⁶ cm⁻³, about 2.5×10¹⁶ cm⁻³, or about 3×10¹⁶ cm⁻³.

At the interface between the second collector region 120B and the third collector region 120C, the doping concentration increases by about an order of magnitude without additional depth into the collector, i.e., increases to a range of about 1×10¹⁶ cm⁻³ to about 5×10¹⁶ cm⁻³. For example, the doping concentration at the interface between the second collector region 120B and the third collector region 120C is about 1×10¹⁶ cm⁻³, about 1.25×10¹⁶ cm⁻³, about 1.5×10¹⁶ cm⁻³ about 1.75×10¹⁶ cm⁻³, about 2×10¹⁶ cm⁻³, about 2.25×10¹⁶ cm⁻³, about 2.5×10¹⁶ cm⁻³, about 2.75×10¹⁶ cm⁻³, about 3×10¹⁶ cm⁻³, about 3.25×10¹⁶ cm⁻³, about 3.5×10¹⁶ cm⁻³, about 3.75×10¹⁶ cm⁻³, about 4×10¹⁶ cm⁻³, about 4.25×10¹⁶ cm⁻³, about 4.5×10¹⁶ cm⁻³, about 4.75×10¹⁶ cm⁻³, or about 5×10¹⁶ cm⁻³.

With continued reference to FIG. 1, the bipolar transistor 100 can include a sub-collector 108 over the substrate 106. The sub-collector 108 can be under the collector. For example, as illustrated in FIG. 1, the sub-collector 108 can be disposed between the third collector region 120C and the substrate 106. The sub-collector 108 can abut the third collector region 120C. The sub-collector 108 can be a flat doped region. In some embodiments, the doping concentration of the sub-collector 108 can be at least one or two orders of magnitude higher than the highest doping concentration of the first collector region 120A or the third collector region 120C. For example, the sub-collector 108 can have a doping concentration on the order of 5×10¹⁸ cm⁻³ and have a thickness of at least about 8000 Å in certain embodiments. The collector contact 140 physically contacting the sub-collector 108 can provide an electrical connection to the first collector region 120A, second collector region 120B, and third collector region 120C.

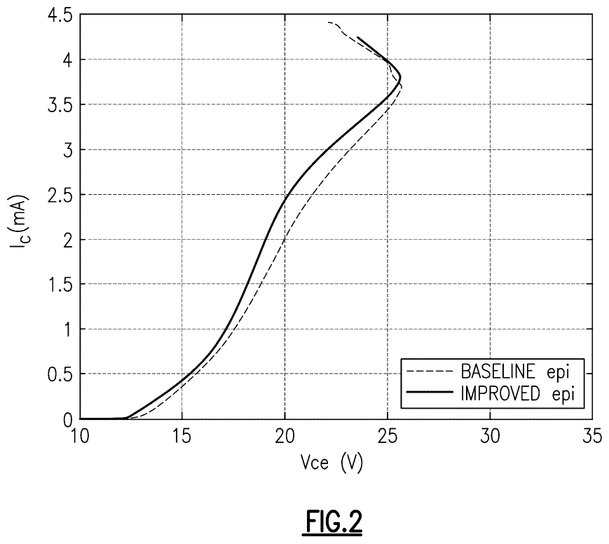

The doping concentration of the third collector region 120C at an interface with the sub-collector 108 can determine a breakdown voltage from the collector to the emitter with the base having a resistor coupled to a potential. Such a breakdown voltage which defines the snapback point of the collector current versus collector-emitter voltage curve can be referred to as “BV_{CEX}.” A higher BV_{CEX} and/or I_{c}_BV_{cex} (the collector current at the snapback point) can increase a safe operating region (SOA). Higher doping in the third collector region 120C at the interface with the sub-collector 108 can expand the SOA by increasing I_{c}_BV_{cex}. Doping the third collector region 120C at the interface with the sub-collector 108 too high can result in a high base-collector junction capacitance and thus a low RF gain of the bipolar transistor 100. In certain embodiments, the doping concentration of the collector at the junction of the collector and the sub-collector is selected from a range of 5×10¹⁶ cm⁻³ to 5×10¹⁷ cm⁻³, e.g., about 5×10¹⁶ cm⁻³, about 5.5×10¹⁶ cm⁻³, about 6×10¹⁶ cm⁻³, about 6.5×10¹⁶ cm⁻³, about 7×10¹⁶ cm⁻³, about 7.5×10¹⁶ cm⁻³, about 8×10¹⁶ cm⁻³, about 8.5×10¹⁶ cm⁻³, about 9×10¹⁶ cm⁻³, about 9.5×10¹⁶ cm⁻³, about 1×10¹⁷ cm⁻³, about 1.5×10¹⁷ cm⁻³, about 2×10¹⁷ cm⁻³, about 2.5×10¹⁷ cm⁻³, about 3×10¹⁷ cm⁻³, about 3.5×10¹⁷ cm⁻³, about 4×10¹⁷ cm⁻³, about 4.5×10¹⁷ cm⁻³, or about 5×10¹⁷ cm⁻³. As an illustrative example, FIG. 2 illustrates a graph of experimental measurements of the breakdown voltage for a state-of-the-art transistor (shown as a dashed line in FIG. 2) and for a transistor having the design of the bipolar transistor 100 shown in FIG. 1 (shown as a solid line in FIG. 2). In FIG. 2, the X-axis corresponds to the collector-emitter voltage (V_{ce}), and the Y-axis corresponds to the collector current I_{c}. As the collector current I_{c} increases, the voltage increases as the peak electric field increases until a threshold current I_{c}_BV_{cex} is reached. At that threshold, the peak electric field has shifted from the base-collector junction towards the collector-sub-collector interface. Increasing the current past the threshold or snapback point can cause the voltage V_{ce} to decrease. Increasing the collector thickness and the doping concentration of the second collector region 120B and/or the third collector region 120C together with increasing the doping concentration at the junction of the collector and the sub-collector can push the snapback point towards the top right corner of the I_{c}-V_{ce} plot in some embodiments. However, increasing the concentration too far may degrade the RF gain of the bipolar transistor 100. FIG. 2 illustrates that the use of a retrograde doping profile in the collector, e.g., in the first collector region 120A, does not impart any significant ruggedness degradation compared to a state-of-the-art transistor.

The base 121 of the bipolar transistor 100 can include P doped GaAs-based (for example, P+ doped GaAs, P+ doped gallium arsenide antimonide (GaAsSb), P+ doped gallium arsenide indium nitride (GaAsInN), P+ doped gallium indium arsenide (GaInAs), P+ doped gallium arsenide phosphide antimonide (GaAsPSb)). The base 121 can have a substantially flat doping profile or a graded doping profile. In certain implementations, the doping concentration of the base 121 can be selected in a range from about 2×10¹⁹ cm⁻³ to 7×10¹⁹ cm⁻³, although other doping concentrations could be used in some embodiments. The thickness of the base 121 can be selected in the range from about 0.035 μm to about 0.14 μm, or 0.05 μm to about 0.12 μm, or 0.05 μm to about 0.09 μm, according to certain implementations, or any values or ranges between any of those thickness values. Any base thicknesses selected from the ranges disclosed herein can be implemented in combination with any of the base doping concentrations selected from the ranges disclosed herein. As one example, the base 121 can have a doping concentration of 5.5×10¹⁹ cm⁻³ and a thickness of 500 Å (0.05 μm). In the bipolar transistor 100 of FIG. 1, the thickness can be the shortest distance between the emitter 128 and the collector, e.g., the first collector region 120A. Any suitable configuration for the base 121 can be used.

The bipolar transistor 100 can include a collector contact 140 to the collector, base contact(s) 138 to the base 121, and an emitter contact 142 to the emitter 128. These contacts can provide an electrical connection to and/or from the bipolar transistor 100. The contacts 140, 138, and 142 can be formed of any suitable conductive material. As illustrated in FIG. 1, the emitter contact 142 can be disposed over a top contact 134, a bottom contact 132, and an emitter cap 126.

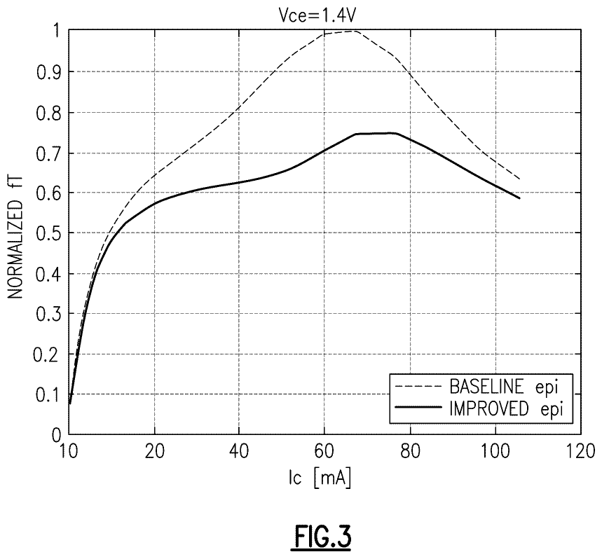

FIG. 3 is a graph that shows experimental measurements of the normalized transition frequency (f_{T}) versus the collector current I_{c}. As disclosed herein, the first collector region (region 120A of FIG. 1) of the collector at the collector-base junction is where electron density has a large impact on the transition frequency (f_{T}), whose value is proportional to the RF gain of a power amplifier. In this region of the transistor, the electron density is highly responsive to the changes in voltage at the base-emitter junction (dV_{be}) or the changes in current density of the collector (dJ_{c}). At the base-collector junction, electrons are depleted and then gradually rise to a higher concentration. The electron concentration and the gradual increase is modulated by the electric field, and thus electron velocity, present near the base-collector junction. An increase in the doping concentration in the collector near the base-collector junction increases the electric field. With the increased electric field near the base-collector junction, the mobility of electrons at the base-collector junction is decreased, thus lowering the electron velocity. Modulating the doping concentration at the front of the collector, i.e., the first collector region 120A, to have a higher electron density and lower electron velocity for the same collector current I_{c} increases the electron transit time, thus lowering or “flattening” the f_{T} and improving the linearity of the bipolar transistor as the RF gain variation correlates strongly with the f_{T} variation under certain DC bias conditions of the bipolar transistor. FIG. 3 illustrates this effect, with the transistor having the design of bipolar transistor 100 in FIG. 1 (shown as a solid line in FIG. 3) having a flatter normalized f_{T} compared to that of the state-of-the-art transistor (shown as a dashed line in FIG. 3).

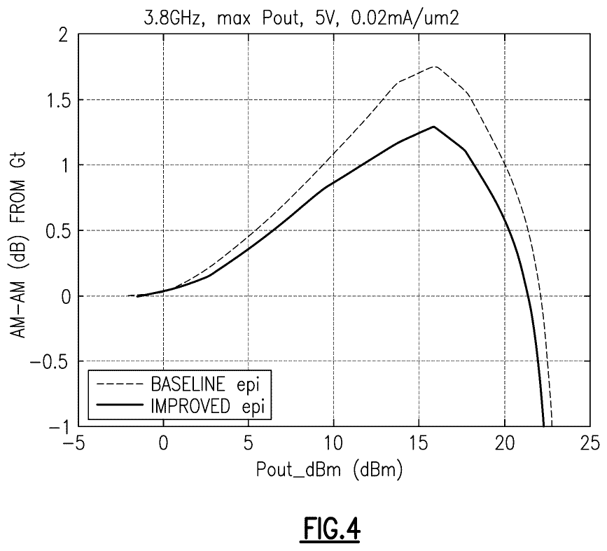

FIG. 4 is a graph that shows experimental measurements of the variation in amplitude from input to output (AM-AM distortion or gain expansion) as a function of the output power (Pₒᵤₜ). As disclosed herein, the AM-AM distortion or gain expansion is a metric of bipolar transistor linearity and a lower AM-AM distortion is indicative of increased linearity of the bipolar transistor. FIG. 4 illustrates the effect of the retrograde doping profile of the collector in a bipolar transistor on the AM-AM distortion. In FIG. 4, the transistor having the design of bipolar transistor 100 in FIG. 1 (shown as a solid line in FIG. 4) has a lower AM-AM distortion across the output power range of the power amplifier (operating at a frequency of 3.8 GHz and a current density on the collector of 0.02 mA/μm²). In contrast, the state-of-the-art transistor (shown as a dashed line in FIG. 4) had a greater AM-AM distortion at the same operational conditions. This reduction in AM-AM distortion is correlated with the “flattened” f_{T} curve illustrated in FIG. 3.

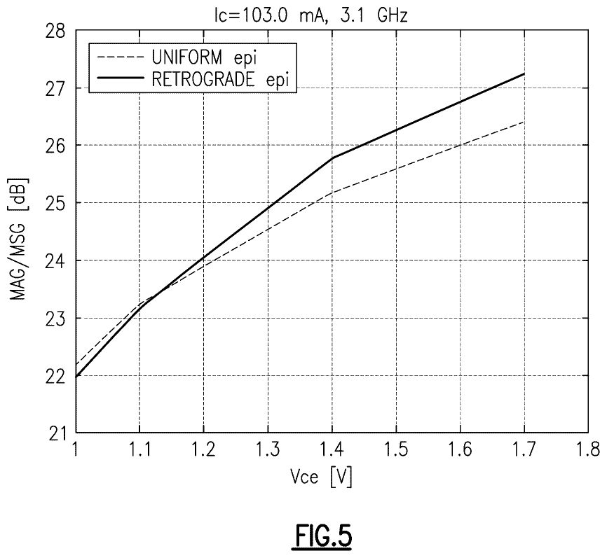

FIG. 5 is a graph that shows experimental measurements of the increase in RF gain (as the maximum available gain (MAG) and maximum stable gain (MSG)) as a function of collector-emitter voltage (V_{ce}). As illustrated in FIG. 5, the transistor having the design of bipolar transistor 100 in FIG. 1 (shown as a solid line in FIG. 5) has a higher RF gain at high current and/or high amplifier output power and low collector-emitter voltage compared to the state-of-the-art transistor (shown as a dashed line in FIG. 5). This measurement confirms that there is no performance degradation, but a performance increase, due to the retrograde doping profile at the first collector region 120A.

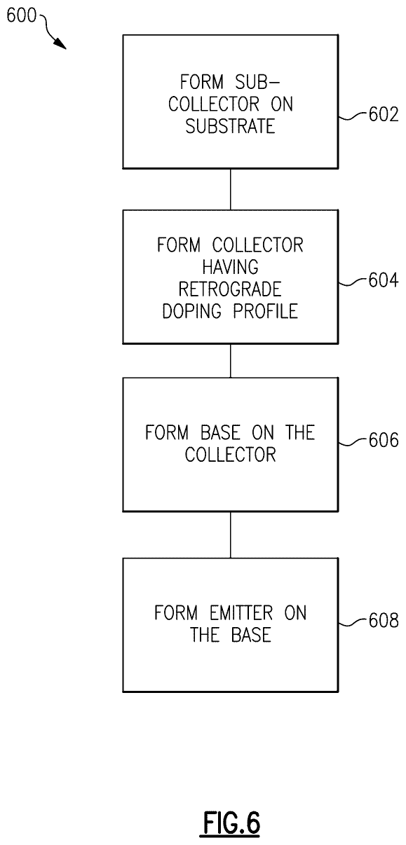

FIG. 6 is an example flow diagram of a process 600 of forming a bipolar transistor according to some embodiments. It will be understood that any of the processes discussed herein may include greater or fewer operations and the operations may be performed in any order, as appropriate. Further, one or more acts of the process can be performed either serially or in parallel. The process 600 can be performed while forming the bipolar transistor 100 of FIG. 1 or any other suitable bipolar transistor disclosed herein, or any combination thereof. At block 602, a sub-collector of a bipolar transistor is formed (e.g., over the substrate). The sub-collector can include any combination of features of the sub-collectors described herein, for example, the sub-collector 108. A collector can be formed that includes a retrograde doping profile at block 604. The retrograde doping profile can be formed by any suitable doping method. The collector can be adjacent to the sub-collector, for example, directly over the sub-collector 108 in the orientation of FIG. 1. The collector can include any combination of features described herein with reference to the first, second, and third collector regions 120A, 120B, and/or 120C of the collector in FIG. 1. The collector can increase the linearity of the bipolar transistor (in some cases while maintaining other useful performance metrics, such as ruggedness), as disclosed herein. At blocks 606 and 608, additional components of the bipolar transistor are formed, such as the base on the collector and the emitter on the base, respectively.

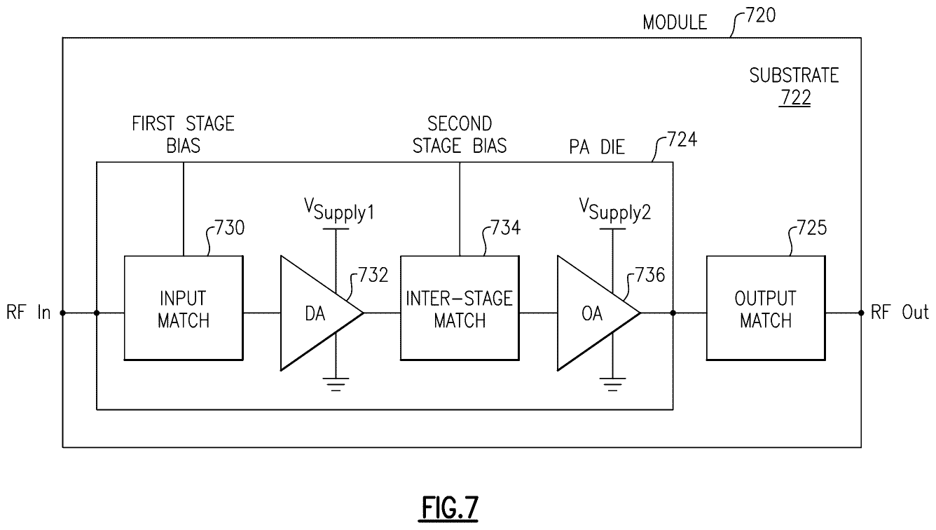

FIG. 7 is a schematic block diagram of a module 720 that can include one or more bipolar transistors 100 of FIG. 1, or any other suitable bipolar transistors disclosed herein, or any combination thereof. The module 720 can be some or all of a power amplifier system. The module 720 can be referred to as multi-chip module and/or a power amplifier module in some implementations. The module 720 can include a substrate 722 (for example, a packaging substrate), a die 724 (for example, a power amplifier die), an output matching network 725, the like, or any combination thereof. Although not illustrated, the module 720 can include one or more other dies and/or one or more circuit elements that are coupled to the substrate 722 in some implementations. The one or more other dies can include, for example, a controller die, which can include a power amplifier bias circuit and/or a direct current-to-direct current (DC-DC) converter. Example circuit element(s) mounted on the packaging substrate can include, for example, inductor(s), capacitor(s), impedance matching network(s), the like, or any combination thereof.

The module 720 can include a plurality of dies and/or other components mounted on and/or coupled to the substrate 722 of the module 720. In some implementations, the substrate 722 can be a multi-layer substrate configured to support the dies and/or components and to provide electrical connectivity to external circuitry when the module 720 is mounted on a circuit board, such as a phone board.

The power amplifier die 724 can receive an RF signal at an input connection RF In of the module 720. The power amplifier die 724 can include one or more power amplifiers, including, for example, multi-stage power amplifiers configured to amplify the RF signal. The power amplifier die 724 can include an input matching network 730, a first stage power amplifier 732 (which can be referred to as a driver amplifier (DA)), an inter-stage matching network 734, a second stage power amplifier 736 (which can be referred to as an output amplifier (OA)), or any combination thereof.

A power amplifier can include the first stage power amplifier 732 and the second stage power amplifier 736. The first stage power amplifier 732 and/or the second stage power amplifier 736 can include one or more bipolar transistors 100 of FIG. 1 or one or more other bipolar transistors disclosed herein, or any combination thereof. Moreover, the bipolar transistors disclosed herein can help the power module 720 and/or the power amplifier die 724 to meet any of the linearity or performance specifications disclosed herein.

The RF input signal can be provided to the first stage power amplifier 732 via the input matching network 730. The matching network 730 can receive a first stage bias signal. The first bias signal can be generated on the PA die 724, outside of the PA die 724 in the module 720, or external to the module 720. The first stage power amplifier 732 can amplify the RF input and provide the amplified RF input to the second stage power amplifier 736 via the inter-stage matching circuit 734. The inter-stage matching circuit 734 can receive a second stage bias signal. The second stage bias signal can be generated on the PA die 724, outside of the PA die 724 in the module 720, or external to the module 720. The second stage power amplifier 736 can generate the amplified RF output signal.

The amplified RF output signal can be provided to an output connection RF Out of the power amplifier die 724 via an output matching network 725. The output matching network 725 can be provided on the module 720 to aid in reducing signal reflections and/or other signal distortions. The power amplifier die 724 can be any suitable die. In some implementations, the power amplifier 724 die is a gallium arsenide (GaAs) die. In some of these implementations, the GaAs die has transistors formed using a heterojunction bipolar transistor (HBT) process.

The module 720 can also include one or more power supply pins, terminals, or connections, which can be electrically connected to, for example, the power amplifier die 724. The one or more power supply pins, terminals, or connections can provide supply voltages to the power amplifiers, such as V_{Supply1} and V_{Supply2}, which can have different voltage levels in some implementations. The module 720 can include circuit element(s), such as inductor(s), which can be formed, for example, by a trace on the multi-chip module. The inductor(s) can operate as a choke inductor and can be disposed between the supply voltage and the power amplifier die 724. In some implementations, the inductor(s) are surface mounted. Additionally, the circuit element(s) can include capacitor(s) electrically connected in parallel with the inductor(s) and configured to resonate at a frequency near the frequency of a signal received on the input connection RF In. In some implementations, the capacitor(s) can include a surface mounted capacitor.

The module 720 can be modified to include more or fewer components, including, for example, additional power amplifier dies, capacitors and/or inductors. For example, the module 720 can include one or more additional matching networks 725. As another example, the module 720 can include an additional power amplifier die, as well as an additional capacitor and inductor configured to operate as a parallel LC circuit disposed between the additional power amplifier die and the power supply pin of the module 720. The module 720 can be configured to have additional pins, such as in implementations in which a separate power supply is provided to an input stage disposed on the power amplifier die 720 and/or implementations in which the module 720 operates over a plurality of bands.

The module 720 can have a low voltage positive bias supply of about 5 V, excellent linearity, high efficiency, large dynamic range, high ruggedness, suitable gain, a small and low profile package (for example, 3 mm×3 mm×0.9 mm with a 10-pad configuration), power down control, support low collector voltage operation, digital enable, not require a reference voltage, CMOS compatible control signals, an integrated directional coupler, or any combination thereof.

In some implementations, the module 720 is a power amplifier module that is a fully matched 10-pad surface mount module developed for Wideband Code Division Multiple Access (WCDMA) applications. This small and efficient module can pack full 1920-1980 MHz bandwidth coverage into a single compact package. Because of high efficiencies attained throughout the entire power range, the module 720 can deliver desirable talk-time advantages for mobile phones. The module 720 can meet the stringent spectral linearity requirements of High-Speed Downlink Packet Access (HSDPA), High Speed Uplink Packet Access (HSUPA), and Long Term Evolution (LTE) data transmission with high power added efficiency. A directional coupler can be integrated into the module 720 and can thus eliminate the need for an external coupler.

The die 724 can be a power amplifier die embodied in a single gallium arsenide (GaAs) Microwave Monolithic Integrated Circuit (MMIC) that includes all active circuitry of the module 720, such as one or more the bipolar transistors 100 of FIG. 1. The MMIC can include on-board bias circuitry, as well as input matching network 730 and inter-stage matching network 734. An output matching network 725 can have a 50Ω load that is embodied separate from the die 724 within the package of the module 720 to increase and/or optimize efficiency and power performance.

The module 720 can be manufactured with a GaAs-based Heterojunction Bipolar Transistor (HBT) BiFET process that provides for all positive voltage DC supply operation while maintaining high efficiency and good ruggedness. The module 720 can provide excellent linearity while maintaining performance metrics. Primary bias to the module 720 can be supplied directly or via an intermediate component from any three-cell Ni—Cd battery, a single-cell Li-Ion battery, or other suitable battery with an output in the range of about 5 V. No reference voltage is needed in some implementations. Power down can be accomplished by setting an enable voltage to 0 V. No external supply side switch is needed as typical “off” leakage is a few microamperes with full primary voltage supplied from the battery, according to some implementations.

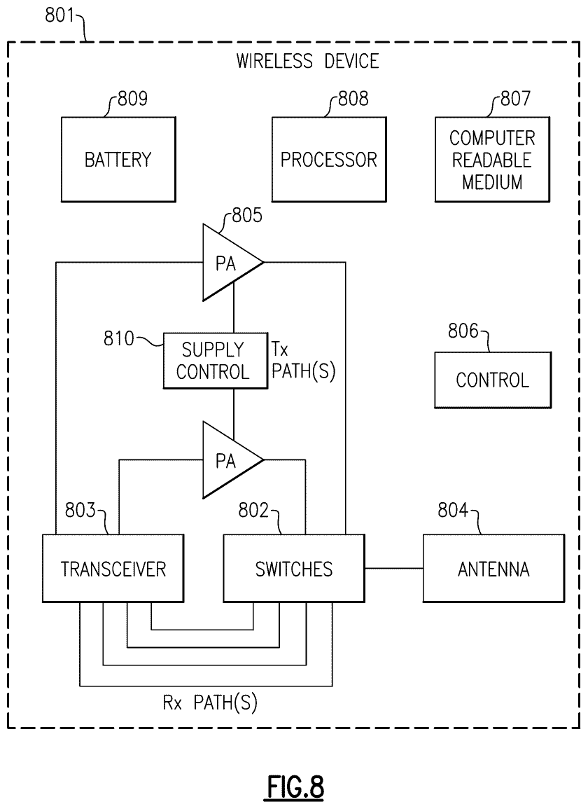

Any of the devices, systems, methods, and apparatus described herein can be implemented in a variety of electronic devices, such as a mobile device, which can also be referred to as a wireless device. FIG. 8 is a schematic block diagram of an example mobile device 801 that can include one or more bipolar transistors 100 of FIG. 1, or any other transistors disclosed herein, or any combination thereof.

Examples of the mobile device 801 can include, but are not limited to, a cellular phone (for example, a smart phone), a laptop, a tablet computer, a personal digital assistant (PDA), an electronic book reader, and a portable digital media player. For instance, the mobile device 801 can be a multi-band and/or multi-mode device such as a multi-band/multi-mode mobile phone configured to communicate using, for example, Global System for Mobile (GSM), code division multiple access (CDMA), 3G, 4G, long term evolution (LTE), and/or 5G.

In certain embodiments, the mobile device 801 can include one or more of a switching component 802, a transceiver component 803, an antenna 804, power amplifiers 805 that can include one or more bipolar transistors 100 of FIG. 1, one or more other bipolar transistors disclosed herein, a control component 806, a computer readable medium 807, a processor 808, a battery 809, and supply control block 810. The transceiver component 803 can generate RF signals for transmission via the antenna 804. Furthermore, the transceiver component 803 can receive incoming RF signals from the antenna 804.

It will be understood that various functionalities associated with the transmission and receiving of RF signals can be achieved by one or more components that are collectively represented in FIG. 8 as the transceiver 803. For example, a single component can be configured to provide both transmitting and receiving functionalities. In another example, transmitting and receiving functionalities can be provided by separate components. Similarly, it will be understood that various antenna functionalities associated with the transmission and receiving of RF signals can be achieved by one or more components that are collectively represented in FIG. 8 as the antenna 804. For example, a single antenna can be configured to provide both transmitting and receiving functionalities. In another example, transmitting and receiving functionalities can be provided by separate antennas. In yet another example, different bands associated with the mobile device 801 can be provided with different antennas.

In FIG. 8, one or more output signals from the transceiver 803 are depicted as being provided to the antenna 804 via one or more transmission paths. In the example shown, different transmission paths can represent output paths associated with different bands and/or different power outputs. For instance, the two example power amplifiers 805 shown can represent amplifications associated with different power output configurations (e.g., low power output and high power output), and/or amplifications associated with different bands.

In FIG. 8, one or more detected signals from the antenna 804 are depicted as being provided to the transceiver 803 via one or more receiving paths. In the example shown, different receiving paths can represent paths associated with different bands. For example, the four example paths shown can represent quad-band capability that some mobile devices 801 are provided with. To facilitate switching between receive and transmit paths, the switching component 802 can be configured to electrically connect the antenna 804 to a selected transmit or receive path. Thus, the switching component 802 can provide a number of switching functionalities associated with an operation of the mobile device 801. In certain embodiments, the switching component 802 can include a number of switches configured to provide functionalities associated with, for example, switching between different bands, switching between different power modes, switching between transmission and receiving modes, or some combination thereof. The switching component 802 can also be configured to provide additional functionality, including filtering of signals. For example, the switching component 802 can include one or more duplexers.

The mobile device 801 can include one or more power amplifiers 805. RF power amplifiers can be used to boost the power of an RF signal having a relatively low power. Thereafter, the boosted RF signal can be used for a variety of purposes, including driving the antenna of a transmitter. Power amplifiers 805 can be included in electronic devices, such as mobile phones, to amplify an RF signal for transmission. For example, in mobile phones having an architecture for communicating under the 3G, 4G, and/or 5G communications standards, a power amplifier can be used to amplify an RF signal. It can be desirable to manage the amplification of the RF signal, as a desired transmit power level can depend on how far the user is away from a base station and/or the mobile environment. Power amplifiers can also be employed to aid in regulating the power level of the RF signal over time, so as to prevent signal interference from transmission during an assigned receive time slot. A power amplifier module can include one or more power amplifiers.

FIG. 8 shows that in certain embodiments, a control component 806 can be provided, and such a component can include circuitry configured to provide various control functionalities associated with operations of the switching component 802, the power amplifier(s) 805, the supply control 810, and/or other operating component(s). In certain embodiments, a processor 808 can be configured to facilitate implementation of various functionalities described herein. Computer program instructions associated with the operation of any of the components described herein may be stored in a computer-readable memory 807 that can direct the processor 808, such that the instructions stored in the computer-readable memory produce an article of manufacture including instructions which implement the various operating features of the mobile devices, modules, etc. as described herein.

As further illustrated in FIG. 8, mobile device 801 also includes the supply control block 810, which can be used to provide power to one or more power amplifiers 805. For example, the supply control block 810 can include a DC-to-DC converter. However, in certain embodiments the supply control block 810 can include other blocks, such as, for example, an envelope tracker configured to vary the supply voltage provided to the power amplifiers 805 based upon an envelope of the RF signal to be amplified. The supply control block 810 can be electrically connected to the battery 809, and the supply control block 810 can be configured to vary the voltage provided to the power amplifiers 805 based on an output voltage of a DC-DC converter. The battery 809 can be any suitable battery for use in the mobile device 801, including, for example, a lithium-ion battery. With at least one power amplifier 805 that includes one or more bipolar transistors 100 of FIG. 1, one or more other bipolar transistors disclosed herein, or any combination thereof, the power consumption of the battery 809 can be reduced and/or the reliability of the power amplifier 805 can be improved, thereby improving performance of the mobile device 801.

Some of the embodiments described above have provided examples in connection with modules and/or electronic devices that include power amplifiers, such as mobile phones. However, the principles and advantages of the embodiments can be used for any other systems or apparatus that have needs for a bipolar transistor with a high level of second channel linearity without sacrificing RF gain.

Systems implementing one or more aspects of the present disclosure can be implemented in various electronic devices. Examples of electronic devices can include, but are not limited to, consumer electronic products, parts of the consumer electronic products, electronic test equipment, etc. More specifically, electronic devices configured implement one or more aspects of the present disclosure can include, but are not limited to, an RF transmitting device, any portable device having a power amplifier, a mobile phone (for example, a smart phone), a telephone, a base station, a femtocell, radar devices, a device configured for communication according to the WiFi and/or Bluetooth standards, a television, a computer monitor, a computer, a hand-held computer, a tablet computer, a laptop computer, a personal digital assistant (PDA), a microwave, a refrigerator, an automobile, a stereo system, a DVD player, a CD player, a VCR, an MP3 player, a radio, a camcorder, a camera, a digital camera, a portable memory chip, a washer, a dryer, a washer/dryer combined device, a copier, a facsimile machine, a scanner, a multi-functional peripheral device, a wrist watch, a clock, etc. Part of the consumer electronic products can include a multi-chip module including an RF transmission line, a power amplifier module, an integrated circuit including an RF transmission line, a substrate including an RF transmission line, the like, or any combination thereof. Moreover, other examples of the electronic devices can also include, but are not limited to, memory chips, memory modules, circuits of optical networks or other communication networks, and disk driver circuits. Further, the electronic devices can include unfinished products.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The words “coupled,” “connected,” and the like, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list. All numerical values provided herein are intended to include similar values within a measurement error.

Moreover, conditional language used herein, such as, among others, “can,” “could,” “might,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments is not intended to be exhaustive or to limit the invention to the precise form disclosed above. While specific embodiments of, and examples for, the invention are described above for illustrative purposes. For example, while processes or blocks are presented in a given order, alternative embodiments may perform routines having acts, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

While certain embodiments of the inventions have been described, these embodiments have been presented by way of example only, and are not intended to limit the scope of the disclosure. For example, various equivalent modifications are possible within the scope of the invention, as those skilled in the relevant art will recognize. Moreover, the elements and acts of the various embodiments described above can be combined to provide further embodiments. Indeed, the methods, systems, apparatus, and articles of manufacture described herein may be embodied in a variety of other forms; furthermore, various omissions, substitutions and changes in the form of the methods, systems, apparatus, and articles of manufacture described herein may be made without departing from the spirit of the disclosure. The accompanying claims and their equivalents are intended to cover such forms or modifications as would fall within the scope and spirit of the disclosure.

What is claimed is:

1. A bipolar transistor formed on a substrate comprising:
a collector, a base disposed over the collector, and an emitter,
the collector having a retrograde doping profile in which a doping concentration is highest at a junction of the base and the collector and decreases through a portion of the collector to about 95% less to about 99.5% less.

2. The bipolar transistor of claim 1 wherein the decrease in doping concentration in the collector is through about one-twentieth to about one-quarter of a total dimension of the collector.

3. The bipolar transistor of claim 1 wherein the bipolar transistor has an output power of at least about 28 dBm within a frequency band centered around about 6.5 GHz.

4. The bipolar transistor of claim 1 wherein the doping concentration in the collector decreases substantially linearly or substantially non-linearly.

5. The bipolar transistor of claim 1 wherein the bipolar transistor has about a 0.3 dB improvement in gain expansion as compared to a similarly constructed bipolar transistor with a collector having a uniformly doped or step-doped concentration.

6. The bipolar transistor of claim 1 wherein the bipolar transistor has approximately the same ruggedness as a function of a voltage at a collector-emitter junction as compared to a similarly constructed bipolar transistor with a collector having a uniform doping concentration.

7. The bipolar transistor of claim 1 wherein the bipolar transistor has about a 35% increase in the transition frequency flatness as compared to a similarly constructed bipolar transistor with a collector having a uniformly doped or step-doped concentration.

8. The bipolar transistor of claim 1 wherein the doping concentration of the collector at the junction of the base and the collector is selected from a range of 3×10¹⁶ cm⁻³ to 6×10¹⁷ cm⁻³.

9. The bipolar transistor of claim 1 wherein the collector has a total thickness of 1 μm to 2 μm.

10. The bipolar transistor of claim 9 wherein the doping concentration in the collector is at a maximum within a first 0.2 μm to 0.4 μm of the base-collector junction.

11. The bipolar transistor of claim 1 further comprising a sub-collector, the collector being disposed between the base and the sub-collector.

12. The bipolar transistor of claim 11 wherein the doping concentration of the collector at the junction of the collector and the sub-collector is selected from a range of 5×10¹⁶ cm⁻³ to 5×10¹⁷ cm⁻³.

13. A power amplifier module comprising a bipolar transistor formed on a substrate, the bipolar transistor comprising:
a collector, a base disposed over the collector, and an emitter, the collector having a retrograde doping profile in which a doping concentration is highest at a junction of the base and the collector and decreases through a portion of the collector to about 95% less to about 99.5% less.

14. The power amplifier module of claim 13 wherein the retrograde doping profile of the collector is configured to provide about a 0.3 dB improvement in gain expansion as compared to a similarly constructed bipolar transistor with a collector having a uniformly doped or step-doped concentration.

15. The power amplifier module of claim 13 wherein the retrograde doping profile of the collector is configured to provide approximately the same ruggedness as a function of a voltage at a collector-emitter junction as compared to a similarly constructed bipolar transistor with a collector having a uniform doping concentration.

16. The power amplifier module of claim 13 wherein the retrograde doping profile of the collector is configured to provide about a 35% increase in transition frequency flatness as compared to a similarly constructed bipolar transistor with a collector having a uniformly doped or step-doped concentration.

17. The power amplifier module of claim 13 wherein the collector has a doping concentration of at the junction of the base and the collector of at least 3×10¹⁶ cm⁻³ in a first about 0.2 μm to about 0.4 μm of thickness of the collector.

18. A method of forming a bipolar transistor on a substrate, the method comprising:
forming a sub-collector on the substrate;
forming a collector on the sub-collector, the collector having a retrograde doping profile in which a doping concentration is highest at a junction of a base and the collector and decreases through a portion of the collector to about 95% less to about 99.5% less;
forming a base on the collector; and
forming an emitter on the base.

19. The method of claim 18 wherein the doping concentration of the collector at the junction of the base and the collector is selected from a range of about 3×10¹⁶ cm⁻³ to about 6×10¹⁷ cm⁻³.

20. The method of claim 18 wherein the doping concentration of the collector at the junction of the collector and the sub-collector is selected from a range of 5×10¹⁶ cm⁻³ to 5×10¹⁷ cm⁻³.
